(19) United States
(12) Patent Application Publication
(10) Pub. No.: US 2011/0068330 A1
(43) Pub. Date: Mar. 24, 2011

(54) LIGHT EMITTING DEVICE

(75) Inventors: Keiko Akimoto, Kanagawa-ken (JP); Kenji Sasaki, Kanagawa-ken (JP); Masato Sawada, Kanagawa-ken (JP)

(73) Assignee: KABUSHIKI KAISHA TOSHIBA, Tokyo (JP)

(21) Appl. No.: 12/876,411

(22) Filed: Sep. 7, 2010

(30) Foreign Application Priority Data
Sep. 18, 2009 (JP) 2009-216892

(51) Int. Cl. H01L 51/52

(52) U.S. Cl. 257/40; 257/E51.018

(57) ABSTRACT

According to one embodiment, a light emitting device includes a first reflective layer, a first light emitting element, a second reflective layer and a second light emitting element stacked in this order. The first reflective layer is configured to reflect light in a first wavelength band. The first light emitting element is configured to emit the light in the first wavelength band. The second reflective layer has transmittance for the light in the first wavelength band being higher than transmittance for light in a second wavelength band different from the first wavelength band. The second light emitting element is configured to emit the light in the second wavelength band.

### CROSS-REFERENCE TO RELATED APPLICATIONS

This application is based upon and claims the benefit of priority from the prior Japanese Patent Application No.2009-216892, filed on Sep. 18, 2009; the entire contents of which are incorporated herein by reference.

### FIELD

Embodiments described herein relate generally to a light emitting device.

### BACKGROUND

Recently, attention has been focused on thin light emitting sources which can be used for display backlights, illumination devices and the like. Such a light emitting device needs to satisfy certain requirements including color temperature, color rendition, or in depending on the mode of use, preference and the like. Depending on such requirements, it is possible to adopt a structure of stacking light emitting elements with different emission colors (see, e.g., JP-A-2006-155940). In such a light emitting device, emission light from the stacked light emitting elements is mixed, which makes it possible to obtain white light with predetermined color rendition, for instance.

### BRIEF DESCRIPTION OF THE DRAWINGS

FIGS. 1A and 1B are principal schematics of a light emitting device;

FIGS. 2A and 2B illustrate the function and effect of the light emitting device;

FIGS. 3A and 3B are principal schematics of a light emitting device;

FIGS. 4A and 4B are principal schematics of a light emitting device; and

FIGS. 5A and 5B are principal schematics of a light emitting device.

### DETAILED DESCRIPTION

The embodiments will now be described with reference to the drawings. In the embodiments, a first reflective layer configured to reflect light in a first wavelength band, a first light emitting element configured to emit light in the first wavelength band, a second reflective layer with transmittance for light in the first wavelength band being higher than transmittance for light in a second wavelength band different from the first wavelength band, and a second light emitting element configured to emit light in the second wavelength band, are stacked in this order.

### First Embodiment

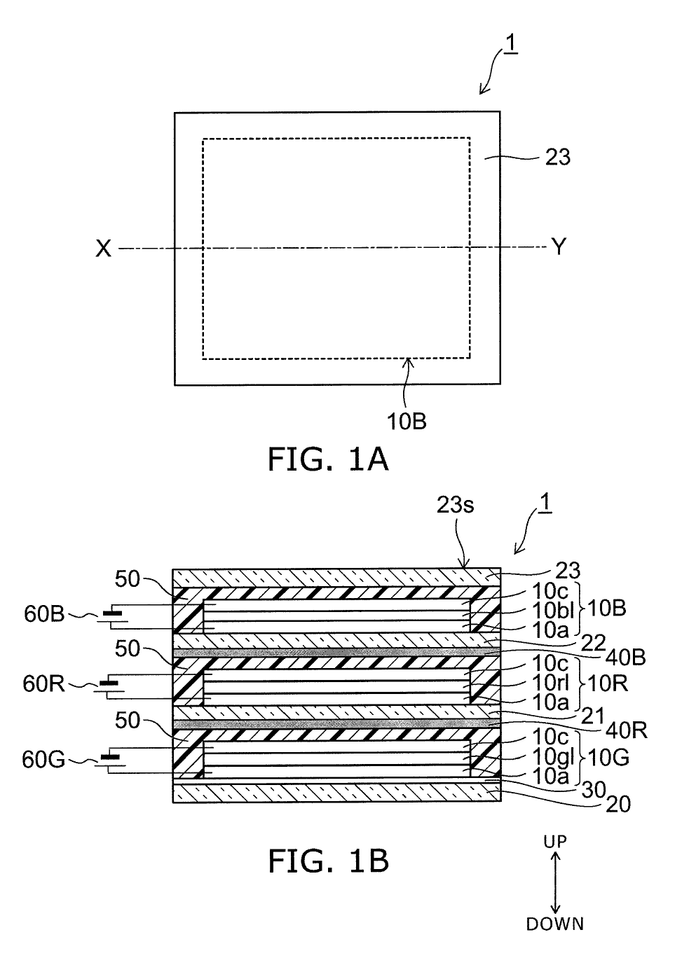

FIGS. 1A and 1B are principal schematics of a light emitting device. FIG. 1A is a principal plan view of the light emitting device 1, and FIG. 1B shows the X-Y cross section of FIG. 1A.

The light emitting device 1 includes a transparent substrate 23 constituting a window member, a substrate 20 opposed to the transparent substrate 23, light emitting elements 10G, 10R, 10B stacked between the transparent substrate 23 and the substrate 20, transparent substrates (light transmissive substrates) 21, 22 provided between the stacked light emitting elements, and dichroic mirrors (reflective layers) 40R, 40B formed on the major surface (upper surface or lower surface) of the transparent substrates 21, 22, respectively.

The light emitting element can illustratively be any of various light emitting elements, such as an organic EL element, an inorganic EL element, or a light emitting diode primarily composed of semiconductor materials.

In the embodiments described below, a description is given mainly of configurations using an organic EL element as an example of the light emitting element.

The light emitting device 1 is a planar light emitting device and has a structure in which a plurality of light emitting elements are stacked with the major surfaces opposed to each other. The planar shape may be a square or rectangle. Alternatively, various other shapes can be used.

Specifically, the light emitting device 1 has a structure in which, for instance, three light emitting elements 10G, 10R, 10B are stacked with the major surfaces opposed to each other. The light emitting elements 10G, 10R, 10B emit green (first wavelength band), red (second wavelength band), and blue (third wavelength band), respectively. The thickness of the light emitting elements 10G, 10R, 10B is illustratively 100 to 500 nm.

The light emitting element 10G (first light emitting element) is provided on the upper surface of the substrate 20 having an area comparable to or larger than the area of the major surface of the light emitting element 10G. The substrate 20 may have a monolayer structure or multilayer structure. A reflective film 30 (first reflective layer) is formed immediately above the substrate 20. That is, this reflective film 30 is interposed between the light emitting element 10G and the substrate 20.

The light emitting element 1OR (second light emitting element) is provided on the upper surface of the transparent substrate 21 having an area comparable to or larger than the area of the major surface of the light emitting element 10R. The transparent substrate 21 may have a monolayer structure or multilayer structure. The dichroic mirror 40R (second reflective layer) is provided on the lower surface side of the transparent substrate 21.

This dichroic mirror 40R reflects light with a red wavelength, and transmits light with a green wavelength emitted from the light emitting element 10G. That is, in the dichroic mirror 40R, the reflectance for light with the red wavelength is higher than the reflectance for green light, and the transmittance for light with the green wavelength is higher than the transmittance for red light. The dichroic mirror 40R like this may be formed on the upper surface side of the transparent substrate 21.

The light emitting element 10B (third light emitting element) is provided on the upper surface of the transparent substrate 22 having an area comparable to or larger than the area of the major surface of the light emitting element 10B. The transparent substrate 22 may have a monolayer structure or multilayer structure. The dichroic mirror 40B (third reflective layer) is provided on the lower surface side of the transparent substrate 22.

This dichroic mirror 40B reflects light with a blue wavelength, and transmits green light emitted from the light emitting element 10G and red light emitted from the light emitting element 10R. Alternatively, the dichroic mirror 40B may transmit light except the blue wavelength. That is, in the dichroic mirror 40B, the reflectance for light with the blue wavelength is higher than the reflectance for green light and red light, and the transmittance for light with the green and red wavelength is higher than the transmittance for blue light. Then, in the third reflective layer (dichroic mirror 40B), the transmittance for the light in the third wavelength band (blue wavelength) is less than the transmittance for the light in the first wavelength band (green wavelength) and the transmittance for the light in the second wavelength band (red wavelength). The dichroic mirror 40B like this may be formed on the upper surface side of the transparent substrate 22.

The transparent substrate 23 having an area comparable to or larger than the area of the major surface of the light emitting element 10B is provided above the light emitting element 10B. Furthermore, a resin member 50 with light transmissivity and insulating property is provided between the transparent substrate 23 and the transparent substrate 22, between the dichroic mirror 40B and the transparent substrate 21, and between the dichroic mirror 40R and the reflective film 30. The resin member 50 is interposed also between the transparent substrate 23 and the light emitting element 10B, between the dichroic mirror 40B and the light emitting element 10R, and between the dichroic mirror 40R and the light emitting element 10G. Furthermore, the upper surface of the transparent substrate 23 serves as a light extraction surface 23s of the light emitting device 1.

The material of the substrate 20 is illustratively a glass, transparent resin, or metal. The material of the transparent substrates 21, 22, 23 is illustratively a glass or transparent resin. The thickness of the substrate 20 and the transparent substrates 21, 22, 23 is 0.1 to 1.0 mm. The substrate 20 and the transparent substrates 21, 22, 23 have light transmissivity.

The material of the reflective film 30 is illustratively silver (Ag) or aluminum (Al).

The material of the resin member 50 is illustratively epoxy resin.

The dichroic mirror 40B, 40R illustratively has a stacked structure in which a multilayer film of dielectric (e.g., SiO₂, Al₂O₃, and TiO₂) and the like is provided on a translucent substrate. Specifically, for instance, by alternately stacking two kinds of different dielectric layers and adjusting the refractive index and thickness of these dielectric layers, a dichroic mirror having a specific reflection/transmission spectrum can be formed like a so-called DBR (distributed Bragg reflector). Here, in the case where the substrate 20 is made of a material having high reflectance such as stainless steel and aluminum (Al), the reflective film 30 may be omitted.

Each light emitting element 10G, 10R, 10B illustratively has an anode 10a and a cathode 10c. The light emitting element 10G, 10R, 10B has light transmissivity. In the case where the light emitting element 10G, 10R, 10B is an organic EL element, a stacked film 10gl, 10rl, 10bl composed of a hole transport layer, a light emitting layer, and an electron transport layer in this order from the anode 10a toward the cathode 10c is provided between the anode 10a and the cathode 10c. When holes and electrons are injected from the anode 10a and the cathode 10c, respectively, into the light emitting layer, light is emitted by recombination of holes and electrons.

The anode 10a is illustratively a transparent electrode made of a material such as indium in oxide (ITO), in oxide (SnO₂), and aluminum-containing zinc oxide (ZnO:Al).

The cathode 10c is a light transmissive electrode illustratively made of an ultrathin metal material such as a magnesium silver alloy (MgAg), magnesium indium alloy (MgIn), and aluminum (Al). The cathode 10c may be covered with a transparent conductive material layer such as an ITO layer.

The hole transport layer is composed of an organic-containing layer. Its material can illustratively be N,N′-diphenyl-N,N′-bis(3-methylphenyl)-1,1′-biphenyl-4,4′-diamine (TPD), N,N′-diphenyl-N,N′-bis(1-naphthylphenyl)-1,1′-biphenyl-4,4′-diamine (α-NPD), or bis(ditolylaminophenyl)cyclohexane (TPAC). The ionization energy of the hole transport layer lies between the work function of the anode 10a and the ionization energy of the light emitting layer.

The light emitting layer is an organic-containing layer, including a host material and a dopant. The host material can illustratively be tris(8-hydroxyquinolinate) aluminum (Alq₃) or the like. The dopant is any of various materials (such as coumarin, quinacridone, styrylamine, and perlyne) developing blue, red, and green.

The light emitting layer is not limited to these materials, but can illustratively be made of Be-benzoquinolinol (BeBq₂), benzothiazole-based, benzimidazole-based, benzoxazole-based and other fluorescent brightening agents, metal chelated oxonium compounds, styrylbenzene-based compounds, distyrylpyrazine derivatives, aromatic dimethylidine-based compounds, naphthalimide derivatives, perylene derivatives, oxadiazole derivatives, aldazine derivatives, cyclopentadiene derivatives, styrylamine derivatives, coumarin-based derivatives, and aromatic dimethylidine derivatives or the like.

The light emitting layer can be made of polymer organic materials as well as low-molecular organic materials. Furthermore, phosphorescent materials such as Btp₂Ir(acac), Ir(ppy)₃, and Flrpic may be used for light emitting materials.

The electron transport layer is composed of an organic-containing layer. Its material can illustratively be Alq₃, oxadiazole derivatives (tBu-PBD), and 1,3,4-oxazole derivatives (OXD). The electron affinity of the electron transport layer lies between the electron affinity of the light emitting layer and the work function of the cathode 10c.

The light emitting elements 10G, 10R, 10B in the light emitting device 1 can be independently controlled by power supplies 60G, 60R, 60B, respectively. Alternatively, light emission of these light emitting elements 10G, 10R, 10B may each be controlled by a single power supply through suitable adjustment circuits. By adjusting the driving voltage of each light emitting element 10G, 10R, 10B, an arbitrary color can be provided from the light emitting device 1.

In the case where the light emitting element is an inorganic EL element, the aforementioned light emitting layer is replaced by a stacked film of a thin-film insulating layer (lower layer), light emitting layer, and thin-film insulating layer (upper layer). In this case, AC power supplies are used as the power supplies 60G, 60R, 60B. The thin-film insulating layer is illustratively made of Y₂O₃, Ta₂O₅, Al₂O₃, and transparent dielectrics such as Si₃N₄, BaTiO₃, and SrTiO₃. The light emitting layer is a phosphor thin film illustratively made of ZnS:Mn or the like.

In the case where the light emitting element is a light emitting diode composed of semiconductor materials, it is primarily composed of, for instance, silicon (Si), gallium arsenide (GaAs), gallium nitride (GaN), and indium gallium nitride (InGaN) or the like.

Next, the function and effect of the light emitting device 1 are described.

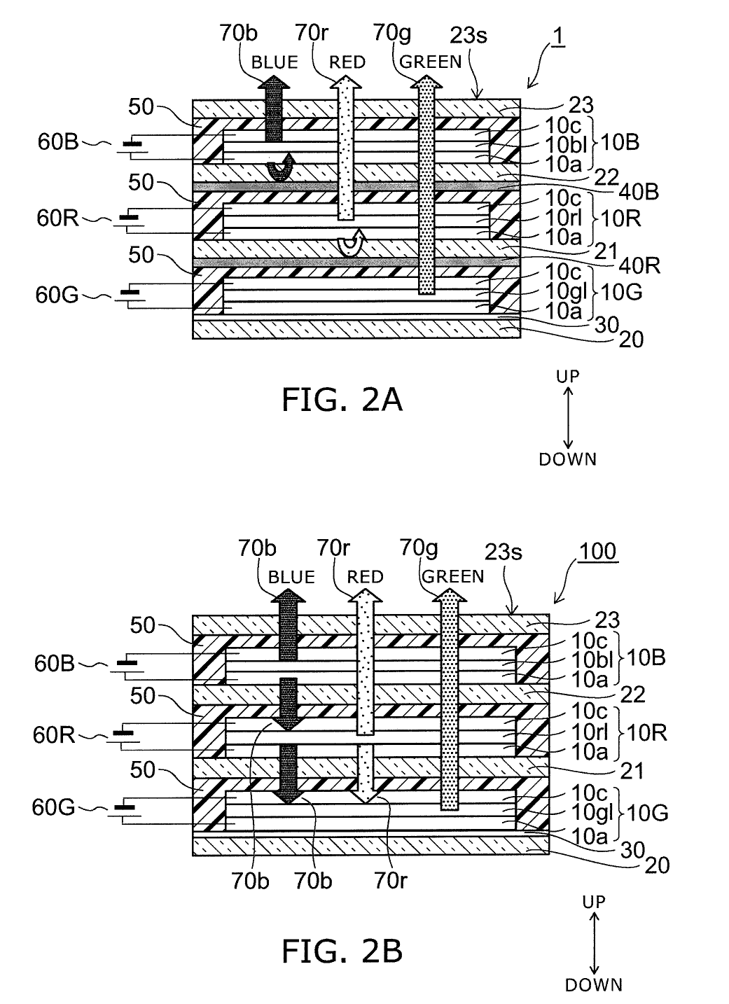

FIGS. 2A and 2B illustrate the function and effect of the light emitting device. FIG. 2A shows the light emitting device 1 according to this embodiment, and FIG. 2B shows a light emitting device 100 of a comparative example. The light emitting device 100 has a structure in which the dichroic mirrors 40B, 40R are removed from the light emitting device 1. The light emitting device 100 has the same planar size as the light emitting device 1.

First, the function and effect of the light emitting device 1 are described.

The power supply 60G is used to drive the light emitting element 10G located at the bottom of the light emitting device 1. Green light 70g is emitted upward and downward from the light emitting element 10G. Here, the reflective film 30 is provided on the substrate 20. Hence, the light 70g directed downward from the light emitting element 10G is reflected by the reflective film 30. Thus, the light 70g generated from the light emitting element 10G is emitted above the substrate 20.

This light 70g reaches the dichroic mirror 40R. However, the dichroic mirror 40R transmits light except red. Thus, the light 70g passes through the dichroic mirror 40R and further through the transparent substrate 21, and reaches the position of the light emitting element 10R.

This light 70g reaches the dichroic mirror 40B. However, the dichroic mirror 40B transmits light except blue. Thus, the light 70g passes through the dichroic mirror 40B and further through the transparent substrate 22, and reaches the position of the light emitting element 10B. Then, this light 70g passes through the transparent substrate 23 and is emitted from a light extraction surface 23s.

On the other hand, the power supply 60R is used to drive the light emitting element 1OR located at the midpoint of the light emitting device 1. Red light 70r is emitted upward and downward from the light emitting element 10R. Here, the dichroic mirror 40R is provided below the transparent substrate 21. The dichroic mirror 40R selectively reflects red light. Hence, the light 70r directed downward from the light emitting element 1OR is reflected by the dichroic mirror 40R. Thus, the light 70r generated from the light emitting element 1OR is emitted above the dichroic mirror 40R.

This light 70r reaches the dichroic mirror 40B. However, the dichroic mirror 40B transmits light except blue. Thus, the light 70r passes through the dichroic mirror 40B and further through the transparent substrate 22, and reaches the position of the light emitting element 10B. Then, this light 70r passes through the transparent substrate 23 and is emitted from the light extraction surface 23s.

Furthermore, the power supply 60B is used to drive the light emitting element 10B located at the top of the light emitting device 1. Blue light 70b is emitted upward and downward from the light emitting element 10B. Here, the dichroic mirror 40B is provided below the transparent substrate 22. The dichroic mirror 40B selectively reflects blue light. Hence, the light 70b directed downward from the light emitting element 10B is reflected by the dichroic mirror 40B. Thus, the light 70b generated from the light emitting element 10B is emitted above the dichroic mirror 40B. Then, the light 70b passes through the transparent substrate 23 and is emitted from the light extraction surface 23s.

Thus, the light emitting device 1 includes the substrate 20 with a plurality of light emitting elements stacked thereon, and dichroic mirrors (reflective layers) each provided between the light emitting elements. Each dichroic mirror reflects light emitted from the closest light emitting element located on the side opposite to the substrate 20, and transmits light emitted from the light emitting elements located therebelow.

For instance, the dichroic mirror 40R, 40B reflects light emitted from the light emitting element neighboring on the transparent substrate (window member) 23 side, and transmits light except this light. Thus, all the green, red, and blue light are efficiently emitted from the light extraction surface 23s. Furthermore, the intensity of each of green, red, and blue light can be independently adjusted.

In contrast, the light emitting device 100 shown in FIG. 2B does not include the dichroic mirrors 40B, 40R.

In the light emitting device 100 like this, the blue light 70b emitted from the light emitting element 10B passes through the transparent substrate 22, which is the foundation of the light emitting element 10B, and reaches the position of the light emitting element 10R. Furthermore, this light 70b may pass through the transparent substrate 21, which is the foundation of the light emitting element 10R, and reach the position of the light emitting element 10G.

The light 70b transmitted through the transparent substrate 22 is absorbed inside the light emitting device 100 or scattered at the layer interface inside the light emitting device 100. Furthermore, the light 70b may be multiply reflected in a particular layer. Such phenomena may occur also for the red light 70r emitted from the light emitting element 10R.

That is, in the light emitting device 100, the light 70b is diffused not only above the light emitting element 10B but also therebelow. Likewise, the light 70r is diffused not only above the light emitting element 1OR but also therebelow. This causes loss for the component of the light 70b, 70r diffused downward. Consequently, the light emitting device 100 has a lower light extraction efficiency or light emission efficiency (the amount of light which can be extracted from the light extraction surface 23s) than the light emitting device 1.

In contrast, the light emitting device 1 includes dichroic mirrors 40B, 40R on the lower surface side of the light emitting element 10B, 10R, respectively. Such a structure can suppress the downward diffusion of the light 70b, 70r. Thus, the light emitting device 1 has a higher light extraction efficiency or light emission efficiency than the light emitting device 100.

Furthermore, with the increase in light emission efficiency, the light emitting device 1 achieves blue intensity and red intensity comparable to those of the light emitting device 100 by lower power than that inputted to the light emitting element 10B, 1OR of the light emitting device 100. Thus, the light emitting device 1 has a longer lifetime than the light emitting device 100.

Furthermore, in the light emitting device 1, the dichroic mirror 40R, 40B is attached to the major surface of the transparent substrate 21, 22. This increases the thermal volume of the foundation of the light emitting element 10B, 10R, and enhances the heat dissipation effect of the light emitting element 10B, 10R. That is, the light emitting elements acting as heat sources are spaced from each other, and thereby the increase in temperature can be suppressed. Consequently, the lifetime of the light emitting element 10B, 1OR is further extended.

Thus, the light emission efficiency and lifetime of the light emitting device 1 are significantly increased.

From the viewpoint of light extraction efficiency, it is preferable to determine the stacking order of the light emitting elements by taking into consideration the absorption of light by other light emitting elements. For instance, the amount of absorption (loss) incurred when the light 70b emitted from the light emitting element 10B passes through the light emitting element 1OR is compared with the amount of absorption (loss) incurred when the light 70r emitted from the light emitting element 1OR passes through the light emitting element 10B. If the former is larger, then as illustrated in FIGS. 1A to 2B, it is preferable that the light emitting element 10B be placed above the light emitting element 10R. That is, with regard to the light emitting element 1OR and the light emitting element 10B, preferably, the light emitting element 10B is placed closer to the light extraction surface 23s.

This also applies to the vertical relationship between the light emitting element 10B and the light emitting element 10G, and the vertical relationship between the light emitting element 1OR and the light emitting element 10G.

Next, variations of the light emitting device are described. In the figures illustrated below, the same members as those in the light emitting device 1 are labeled with like reference numerals, and the detailed description of like members and like configurations is omitted as appropriate. Also in the variations illustrated below, a description is given by taking an organic EL element as an example of the light emitting element.

### Second Embodiment

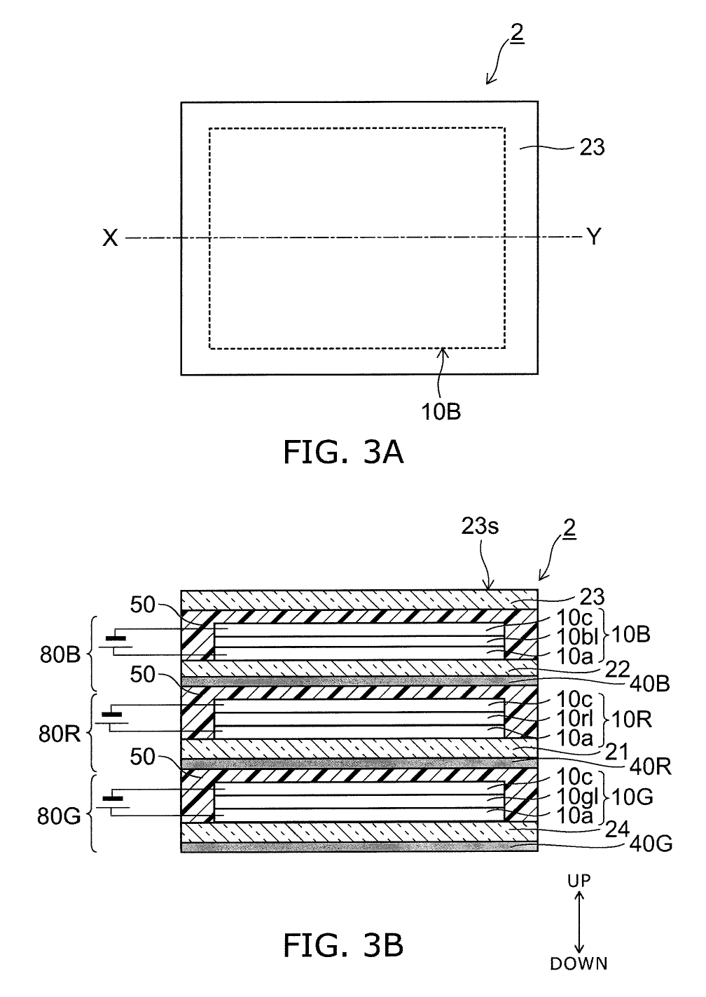

FIGS. 3A and 3B are principal schematics of a light emitting device. FIG. 3A is a principal plan view of the light emitting device 2, and FIG. 3B shows the X-Y cross section of FIG. 3A.

In the light emitting device 2, the aforementioned substrate 20 is replaced by a transparent substrate 24.

For instance, the light emitting element 10G is provided on the upper surface of the transparent substrate 24 having an area comparable to or larger than the area of the major surface of the light emitting element 10G. The transparent substrate 24 may have a monolayer structure or multilayer structure. The light emitting device 2 does not include the aforementioned reflective film 30, but a dichroic mirror 40G (fourth reflective layer) is provided on the lower surface side of the transparent substrate 24. The material of the transparent substrate 24 is illustratively a glass or transparent resin. The dichroic mirror 40G illustratively has a stacked structure in which a multilayer film of dielectric (e.g., SiO₂, Al₂O₃, and TiO₂) and the like is provided on a mirror surface.

This dichroic mirror 40G reflects light with a green wavelength, and transmits light except the green wavelength. That is, in the dichroic mirror 40G, the reflectance for light with the green wavelength is higher than the reflectance for red light and blue light, and the transmittance for light with the red and blue wavelength is higher than the transmittance for green light. Then, in the fourth reflective layer (dichroic mirror 40G), the transmittance for the light in the first wavelength band is less than the transmittance for the light in the second wavelength band and the transmittance for the light in the third wavelength band. The dichroic mirror 40G like this may be formed on the upper surface side of the transparent substrate 24. The upper surface of the transparent substrate 23 serves as the light extraction surface 23s of the light emitting device 2.

That is, the light emitting device 2 has a structure in which a unit 80G including the dichroic mirror 40G, the transparent substrate 24, and the light emitting element 10G, a unit 80R including the dichroic mirror 40R, the transparent substrate 21, and the light emitting element 10R, and a unit 80B including the dichroic mirror 40B, the transparent substrate 22, and the light emitting element 10B, are stacked.

Also in the light emitting device 2 like this, the green light 70g is emitted upward and downward from the light emitting element 10G. Here, the dichroic mirror 40G is provided below the transparent substrate 24. The dichroic mirror 40G selectively reflects green light. Hence, the light 70g directed downward from the light emitting element 10G is reflected by the dichroic mirror 40G. Thus, the light 70g generated from the light emitting element 10G is emitted above the dichroic mirror 40R. That is, the light emitting device 2 also achieves an effect similar to that of the light emitting device 1

Furthermore, in the light emitting device 2, the transparent substrate 24, which is transparent, and the dichroic mirror 40G transmitting light except green are used as the foundation of the light emitting element 10G. Thus, an additional light emitting unit can be provided below the unit 80G. This increases the design flexibility of the light emitting device 2.

In particular, if at least one of the unit 80R and the unit 80B is additionally provided below the unit 80G, the light 70r or light 70b can be emitted with higher intensity.

### Third Embodiment

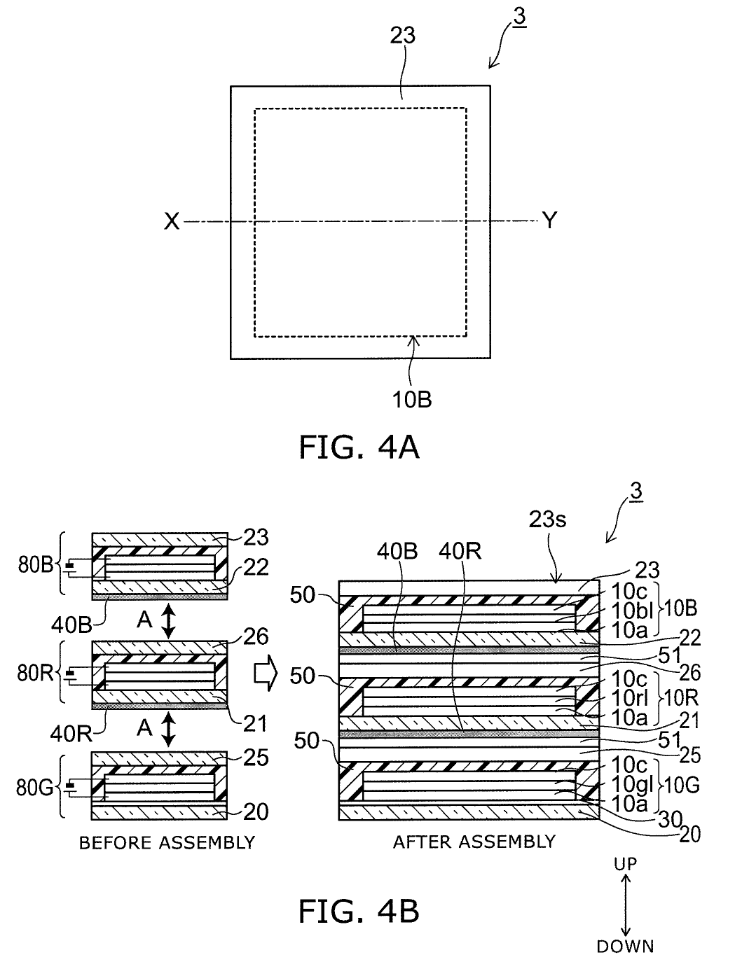

FIGS. 4A and 4B are principal schematics of a light emitting device. FIG. 4A is a principal plan view of the light emitting device 3, and FIG. 4B shows the X-Y cross section of FIG. 4A. FIG. 4B shows cross sections before and after assembly of the light emitting device.

The light emitting device 3 has a structure in which each light emitting element 10G, 10R, 10B is sealed in between opposed substrates. For instance, the resin member 50 is sealed in between the reflective film 30 and a transparent substrate 25, between the transparent substrate 21 and a transparent substrate 26, and between the transparent substrate 22 and the transparent substrate 23. Furthermore, the resin member 50 is filled also between each light emitting element and the transparent substrate 23, 25, 26, and the light emitting element 10G, 10R, 10B is sealed with the resin member 50. The material of the transparent substrate 25, 26 is illustratively a glass or transparent resin. The transparent substrate 25, 26 has light transmissivity.

Here, the unit 80G (first unit) in which the substrate 20, the reflective film 30, the light emitting element 10G, and the transparent substrate 25 are stacked in this order, the unit 80R (second unit) in which the dichroic mirror 40R, the transparent substrate 21, the light emitting element 10R, and the transparent substrate 26 are stacked in this order, and the unit 80B (third unit) in which the dichroic mirror 40B, the transparent substrate 22, the light emitting element 10B, and the transparent substrate 23 are stacked in this order, are manufactured independently (see the left side of FIG. 4B). Then, these units 80G, 80R, 80B are stacked via a transparent resin member 51 in the direction of arrow A (see the right side of FIG. 4B). The resin member 51 is illustratively made of a cohesive material, adhesive material or the like. The resin member 51 has light transmissivity.

Thus, in the light emitting device 3, the adjacent units including the dichroic mirror and the light emitting element can be separated from each other. The light emitting device 3 like this also achieves an effect similar to that of the light emitting device 1.

Furthermore, in the light emitting device 3, because the units 80G, 80R, 80B are independently prepared, the combination of the units can be easily changed depending on the purpose of the light emitting device.

Furthermore, by using a cohesive material as the resin member 51, the units can be easily stuck to and separated from each other. This facilitates unit replacement.

### Fourth Embodiment

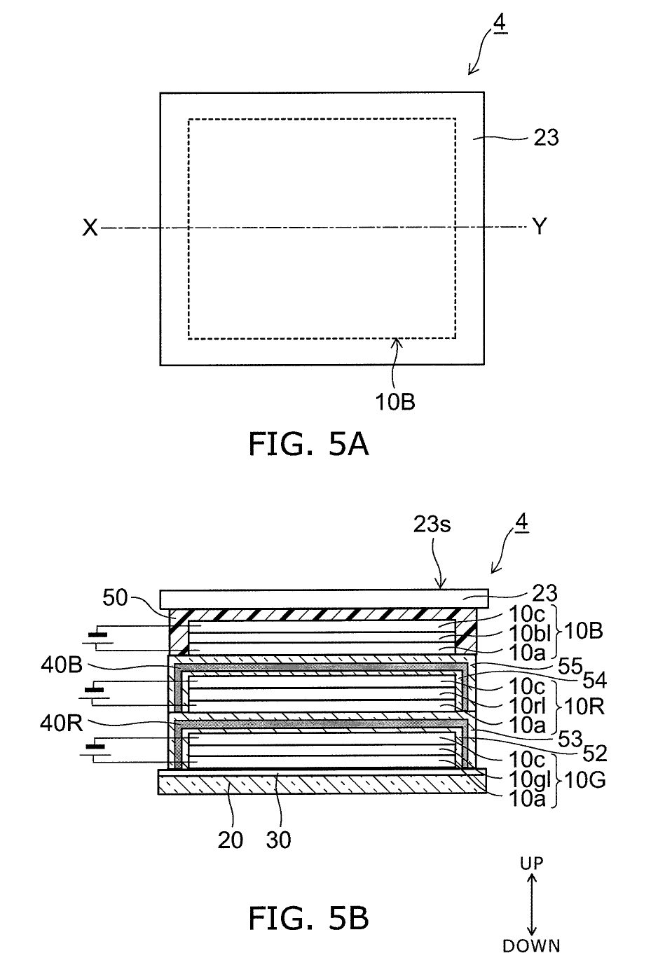

FIGS. 5A and 5B are principal schematics of a light emitting device. FIG. 5A is a principal plan view of the light emitting device 4, and FIG. 5B shows the X-Y cross section of FIG. 5A.

The light emitting device 4 has a structure in which the aforementioned transparent substrates 21, 22 are removed.

The light emitting element 10G of the light emitting device 4 is provided on the upper surface of the substrate 20 having an area comparable to or larger than the area of the major surface of the light emitting element 10G. A reflective film 30 is formed immediately on the substrate 20. That is, this reflective film 30 is interposed between the light emitting element 10G and the substrate 20. The upper surface and the side surface of the light emitting element 10G are covered with a buffer layer 52. The dichroic mirror 40R is provided on the buffer layer 52. A buffer layer 53 is provided on the dichroic mirror 40R. The dichroic mirror 40R is sandwiched between the buffer layer 52 and the buffer layer 53.

Furthermore, the light emitting element 1OR is provided on the buffer layer 53 above the major surface of the light emitting element 10G. The upper surface and the side surface of the light emitting element 1OR are covered with a buffer layer 54. The dichroic mirror 40B is provided on the buffer layer 54. A buffer layer 55 is provided on the dichroic mirror 40B. The dichroic mirror 40B is sandwiched between the buffer layer 54 and the buffer layer 55.

Furthermore, a resin member 50 is provided between the transparent substrate 23 and the buffer layer 55. The resin member 50 is interposed also between the transparent substrate 23 and the light emitting element 10B.

The material of the buffer layer 52, 53, 54, 55 is illustratively silicon oxide (SiO₂), alumina (Al₂O₃) and the like. The buffer layer 52, 53, 54, 55 has light transmissivity. By providing the buffer layer 52, 53, 54, 55 between the dichroic mirror and the light emitting element, impurity diffusion from the dichroic mirror into the light emitting element is suppressed, and the adhesion strength between the dichroic mirror and the light emitting element is increased. Here, at least one of the buffer layers 52, 53, 54, 55 may be omitted as necessary. For instance, this embodiment also includes the configuration in which the light emitting elements 10R, 10B are provided immediately on the dichroic mirrors 40R, 40B, respectively.

Thus, in the light emitting device 4, the transparent substrates 21, 22 are removed, and the light emitting elements 10R, 10B are provided above the dichroic mirrors 40R, 40B.

The light emitting device 4 like this also achieves an effect similar to that of the light emitting device 1. Furthermore, in the light emitting device 4, because the transparent substrates 21, 22 are removed, loss due to absorption and scattering of the light 70b, 70g, 70r is further reduced. This further increases the light emission efficiency.

The embodiments have been described with reference to examples. The light emitting devices described above achieve sufficient characteristics in terms of color temperature, color rendition and the like depending on the use environment. That is, the light emitting device of the present embodiments can provide sufficient brightness as a light source and realize long lifetime. Furthermore, the light emission color can be suitably adjusted as necessary. That is, the light emitting device of the present embodiments can provide an arbitrary color more efficiently and easily.

The embodiments are not limited to the above examples. That is, these examples can be suitably modified by those skilled in the art, and such modifications are also encompassed within the scope of the embodiments as long as they include the features of the embodiments. For instance, the components of the above examples and the layout, material, condition, shape, size and the like thereof are not limited to those illustrated, but can be suitably modified.

For instance, in the examples of the light emitting elements, the number of them is not limited to three, such as the light emitting elements 10G, 10R, 10B. Furthermore, the order of stacking the light emitting elements 10G, 10R, 10B illustrated in the figures is merely an example, and not limited to this stacking order. For instance, as shown in FIG. 2A, the light emitting element located on the upper layer side undergoes less absorption by the light emitting elements and reflective layers located thereabove (see the length of the arrows). Thus, the light emitting element located on the upper layer side can be driven by a lower voltage (or current), and its lifetime can be extended. Hence, preferably, among the light emitting elements 10G, 10R, 10B, the light emitting element (e.g., blue light emitting element) having a relatively short lifetime (the lifetime for operation under the rated condition) is located on the upper layer side.

Furthermore, the components of the above embodiments can be combined with each other as long as technically feasible, and such combinations are also encompassed within the scope of the embodiments as long as they include the features of the embodiments.

Furthermore, those skilled in the art can conceive various modifications and variations within the spirit of the embodiments, and it is understood that such modifications and variations are also encompassed within the scope of the embodiments. For instance, the light emitting device in the present embodiments is applicable also to a display device including a plurality of light emitting elements, and such a display device is encompassed within the scope of the embodiments.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the devices and methods described herein may be made without departing from the spirit of the inventions. The accompanying claims and their equivalents are intended to cover such forms or modifications as would fall within the scope and spirit of the invention.

1. A light emitting device comprising, stacked in this order:
a first reflective layer configured to reflect light in a first wavelength band;
a first light emitting element configured to emit the light in the first wavelength band;
a second reflective layer with transmittance for the light in the first wavelength band being higher than transmittance for light in a second wavelength band different from the first wavelength band; and
a second light emitting element configured to emit the light in the second wavelength band.

2. The device according to claim 1, wherein the light in the first wavelength band emitted from the first light emitting element is extracted through the second reflective layer and the second light emitting element.

3. The device according to claim 1, wherein the first light emitting element is one of an organic EL element and an inorganic EL element.

4. The device according to claim 1, wherein the first light emitting element has a thickness of 100 nm to 500 nm.

5. The device according to claim 1, wherein the second light emitting element is one of an organic EL element and an inorganic EL element.

6. The device according to claim 1, wherein the second light emitting element has a thickness of 100 nm to 500 nm.

7. The device according to claim 1, wherein the second reflective layer includes a multilayer film of dielectric.

8. The device according to claim 1, further comprising:
a buffer layer between the first light emitting element and the second reflective layer.

9. The device according to claim 1, further comprising:
a third light emitting element stacked on a side of the second light emitting element opposite to the first light emitting element and configured to emit light in a third wavelength band different from the first and second wavelength bands; and
a third reflective layer with transmittance for the light in the third wavelength band being less than the transmittance for the light in the first wavelength band and the transmittance for the light in the second wavelength band, the third reflective layer being interposed between the second light emitting element and the third light emitting element.

10. The device according to claim 9, wherein
the light in the first wavelength band emitted from the first light emitting element is extracted through the second reflective layer, the second light emitting element, the third reflective layer, and the third light emitting element, and
the light in the second wavelength band emitted from the second light emitting element is extracted through the third reflective layer and the third light emitting element.

11. The device according to claim 9, wherein a first amount of absorption incurred when the light in the third wavelength band passes through the second light emitting element is larger than a second amount of absorption incurred when the light in the second wavelength band passes through the third light emitting element.

12. The device according to claim 9, wherein the third light emitting element is one of an organic EL element and an inorganic EL element.

13. The device according to claim 9, wherein the third light emitting element has a thickness of 100 nm to 500 nm.

14. The device according to claim 9, wherein the third reflective layer includes another multilayer film of dielectric.

15. The device according to claim 9, wherein intensity of the light emitted from the first light emitting element, intensity of the light emitted from the second light emitting element, and intensity of the light emitted from the third light emitting element can be controlled independently.

16. The device according to claim 9, wherein the first reflective layer is removed, the device further including:
a fourth reflective layer with the transmittance for the light in the first wavelength band being less than the transmittance for the light in the second wavelength band and the transmittance for the light in the third wavelength band, the fourth reflective layer being provided on a side of the first light emitting element opposite to the second light emitting element.

17. The device according to claim 9, wherein a first unit including the first light emitting element and the first reflective layer, a second unit including the second light emitting element and the second reflective layer, and a third unit including the third light emitting element and the third reflective layer, can be separated from each other.

18. The device according to claim 9, further comprising:
another buffer layer between the second light emitting element and the third reflective layer.

19. The device according to claim 16, wherein the fourth reflective layer includes still another multilayer film of dielectric.
